(19) United States
(12) Patent Application Publication
(10) Pub. No.: US 2010/0187638 A1
(43) Pub. Date: Jul. 29, 2010

(54) ANTI-FUSE CELL AND ITS MANUFACTURING PROCESS

(75) Inventors: Bertrand Borot, Le Cheylas (FR); Roberto Maurizio Gonella, Echirolles (FR); Sebastien Fabre, Eybens (FR)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/722,974

(22) PCT Filed: Dec. 23, 2005
(86) PCT No.: PCT/IB05/57150

§ 371 Date: Mar. 19, 2010

(30) Foreign Application Priority Data
Dec. 27, 2004 (EP) 04107005.3

(51) Int. Cl. H01L 23/525; H01L 21/768

(52) U.S. Cl. 257/379; 257/530; 438/467; 257/E23.147; 257/E21.591

(57) ABSTRACT

An anti-fuse cell includes a standard MOS transistor of an integrated circuit, with source (7) and drain (8) regions covered with a metal silicide layer (12, 13), and at least one track (24) of a resistive layer at least partially surrounding said MOS transistor, and adapted to pass a heating current such that the metal of said metal silicide diffuses across drain and/or source junctions.

### BACKGROUND OF THE INVENTION

1. Field of the Invention

The present invention relates to one-time programmable cells for use in integrated circuits, and more particularly, anti-fuse cells.

2. Discussion of the Related Art

One-time programmable cells are cells which can be programmed from one state to another on one occasion, after which further modification is not possible, and the result is non-volatile.

Included in this category are fuses, which can be divided into fuses and anti-fuses. In the case of fuses, pre-existing connections are broken permanently during the programming whereas for anti-fuses, permanent connections are made between previously unconnected nodes.

A first type of fuse consists of a polysilicon track with a narrowed section and terminals for the application of a current. The track presents a resistance of a few tens of ohms between the terminals. When a high current is passed through the fuse, localized heating of the narrowed section occurs and fuses the track, making the resistance greater than one megohm. During the fusing process, the surrounding layers are liable to be damaged significantly, and the break is sometimes unreliable because residual filaments of polysilicon can remake the connection.

A second type of fuse consists of a metal track which provides a resistance of less than one ohm between the terminals. To program the fuse, laser radiation is used to fuse a portion of the track whereby a break occurs, creating a resistance greater than one megohm.

A first type of anti-fuse consists of an insulated gate MOS transistor. The terminals of the anti-fuse are formed by the gate electrode on one hand and the source and drain connected in common on the other, between which is presented a resistance greater than one megohm for the un-programmed fuse. The application of a high voltage between the gate and the substrate causes the rupture of the gate oxide creating a resistance in the order of hundreds of ohms between the gate electrode and the common source/drain electrodes.

A second type of anti-fuse consists of a MOS transistor connected in the off-state, its source and drain electrodes forming the terminals of the anti-fuse cell. When a high voltage is applied between the source and the drain of the MOS transistor, inducing the passage of a high current, permanent defects bridging the source-channel and drain-channel junctions are created. This results in a permanent connection of a few kilo-ohms between said source and drain

So, generally, the electrically programmable fuses and anti-fuses, such as the above, have the disadvantage of requiring a high voltage for their programming, and hence a specific voltage supply source. Moreover, this voltage is significantly above the normal operating voltages of an integrated circuit technology, which imposes the use of special/non-standard devices and process options.

The non-electrically programmable fuses present the disadvantage that programming is only possible while the integrated circuits are still in wafer form at the manufacturing site. Thus programming of product after packaging, for example by the end customer, is impossible. This programming is also time-consuming.

Also, generally known anti-fuses present a relatively high resistance when closed, excluding them from use in many applications, and often imposing an additional discriminator circuit to detect whether or not the link is closed.

Furthermore, generally known fuses and anti-fuses present a disadvantage in that the effect of programming cannot be verified without actually programming the cell. The decision to program a cell, often based on a prior measurement and a calculation, is open to error which results in the entire integrated circuit being rejected.

### SUMMARY OF THE INVENTION

The present invention aims at solving at least some of the problems present in the prior art.

An object of the present invention is to provide a cell which can be programmed with a low voltage.

Another object of the present invention is to provide a fuse cell which can be programmed after integrated circuit packaging.

Another object of the present invention is to provide an anti-fuse cell with a resistance less than ten ohms in the programmed state and a very high resistance in the un-programmed state.

Another object of the present invention is to provide a fuse cell where the fusing process is not liable to impair neighboring structures and the resulting link is reliable.

Another object of the present invention is to provide an anti-fuse cell associated with verification of the intended programming decisions.

To attain these objects, the present invention provides an anti-fuse cell including a MOS transistor of a MOS integrated circuit, with source and drain regions covered with a metal silicide layer, and at least one track of a resistive layer at least partially surrounding said MOS transistor, and adapted to pass a heating current such that the metal of said metal silicide diffuses across drain and/or source junctions.

The present invention also provides a method of manufacturing an anti-fuse cell in an integrated circuit including standard MOS transistors, having source and drain regions containing a layer of metal silicide and being surrounded by insulating field regions, wherein each anti-fuse cell is made of an additional MOS transistor, and said method includes the following steps:

providing insulating field regions wider for said additional transistor than for said standard MOS transistors,

forming simultaneously said additional transistor and said standard MOS transistors,

forming at least one resistive track on the insulating field region around the periphery of said additional MOS transistor, simultaneously with the conductive layer of gates of the transistors.

The foregoing objects, features, and advantages of the present invention, as well as others, will be discussed in detail in the following non-limiting description of specific embodiments in connection with the accompanying drawings.

### BRIEF DESCRIPTION OF THE DRAWINGS

FIG. 1 is a cross sectional view illustrating an example of standard MOS transistors.

FIG. 2 is a cross sectional view illustrating an embodiment of the present invention.

FIG. 3 is a view from above of the embodiment of FIG. 2.

As is conventional in the field of the representation of semiconductors, the various dimensions of the elements shown in the figures are simplified and are not drawn to scale. Those skilled in the art will know how to choose the junction depths and lateral dimensions according to the desired performances.

### DETAILED DESCRIPTION

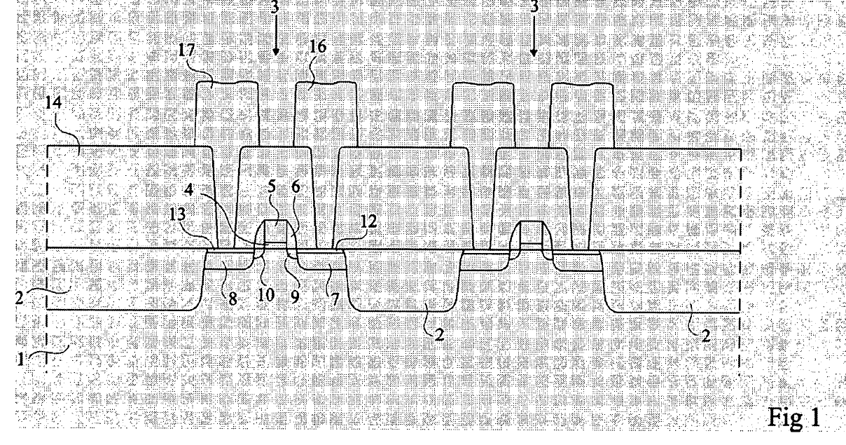

FIG. 1 is a cross sectional view of two conventional MOS transistors. This drawing is extremely simplified in that only the features useful to the discussion of the present invention are shown. Each MOS transistor is formed in a substrate 1, and surrounded by an insulating field region 2 of a certain width, that delimits an active area 3. Each MOS transistor comprises a gate dielectric 4, a gate electrode 5, surrounded by insulating spacers 6, source and drain regions 7 and 8 comprising LDD extensions 9 and 10. A layer of metal silicide 12 covers the upper surface of the source/drain regions 7, 8. A dielectric layer 14 covers the MOS transistor and insulating field regions. Vias 16, 17 contact the source and drain regions 7 and 8. Other interconnection structures (not shown) are formed over the wafer. Those skilled in the art will know variations of such a MOS transistor. In particular the MOS transistors are often formed not directly in the substrate but in specifically doped wells of different conductivity types.

According to a basic aspect of the invention, an anti-fuse cell according to the invention, manufactured in an integrated circuit including standard MOS transistors, uses elements identical to at least some of said standard MOS transistors.

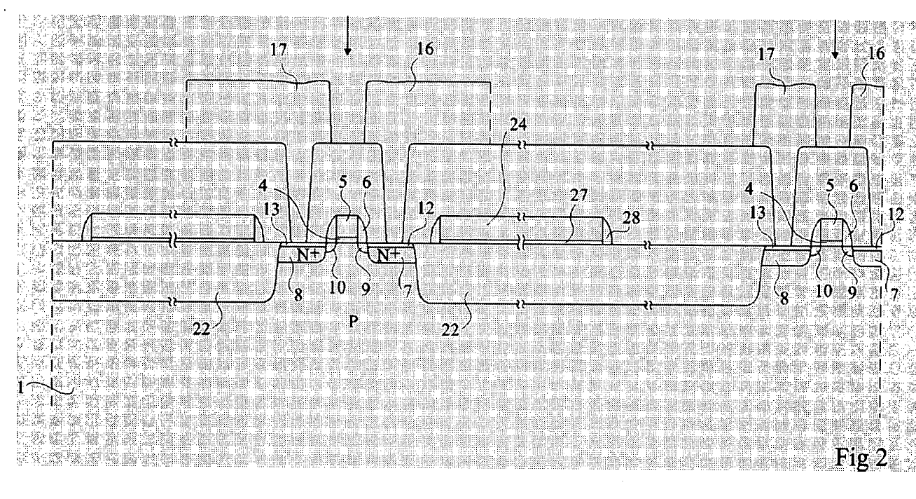

FIG. 2 is a cross sectional view illustrating, in the right-hand portion, a standard MOS transistor, and on the left-hand portion, an anti-fuse cell according to an embodiment of the invention. The structure on the right-hand portion of FIG. 2 shall not be disclosed again as it is strictly identical to the structure disclosed in connection with FIG. 1.

The anti-fuse cell according to the invention includes exactly the same elements as the standard MOS transistor shown on the right-hand portion of the figure and, accordingly, the constitutive portions of the anti-fuse cell are designated by the same references.

It is emphasized that the active area around the MOS transistor of an anti-fuse cell is delimited by an insulating field region 22 that is generally wider than the usual insulating field region 2 between standard MOS transistors.

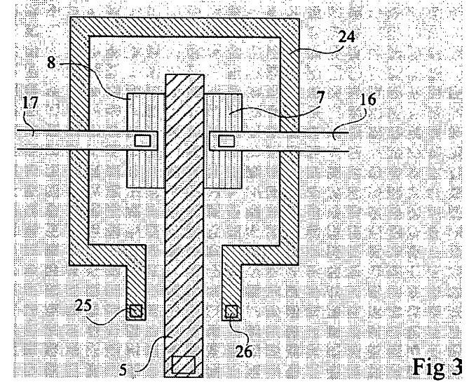

The internal periphery of the insulating field region in the close neighborhood of the active area is covered by a conductive track 24 that can be better seen in the top view of FIG. 3. The track 24 includes terminals 25, 26 to which a supply voltage can be applied.

According to a preferred implementation of the invention, track 24 is formed simultaneously with the gates of the MOS transistors. This is why, in FIG. 2, an underlying insulating layer 27 corresponding to the gate oxide layer 4 and spacers 28 corresponding to the spacers 6 are shown.

The operation and the programming of the anti-fuse cell according to the invention will be disclosed hereinafter.

Immediately after manufacturing, the transistor of the anti-fuse cell according to the invention has the same features as a conventional MOS transistor, i.e. in the absence of a voltage on its gate, it presents a very high resistance between its source and drain terminals 16, 17.

To program the anti-fuse cell, a voltage is applied to terminals 25, 26 of the conductive track 24. This causes a heating of the neighboring region and in particular of the MOS structure situated inside the track. The heating is selected to be sufficient for obtaining a temperature such that the metal contained in the metal silicide (layers 12 and 13) diffuses inside the silicon. When the metal of at least one of the source or drain metal silicide attains the substrate through the drain or source region 7 or 8, or the LDD region 9 or 10, the corresponding junction is no longer rectifying. If only one junction is shorted, the device then operates as a diode. If both drain and source junctions are shorted, the device operates as a resistor. Due to the small size of presently manufactured MOS transistors, this resistor will have a very low value. This value is all the smaller as the diffusion depth from the metal silicide layer is increased.

Also, the invention draws advantage from the fact that silicon oxide is more thermally insulating than silicon. Accordingly, in particular if the field regions correspond to shallow trench isolation (STI) having a larger depth than the drain and source regions, it will be understood that the region situated at the level of and just under the MOS transistor will undergo a larger temperature increase than the region situated under the conductive track. Also, it will be emphasized that the conductive track is arranged on an internal side of the peripheral field oxide so that the transistors arranged on the other side of the conductive track are not accidentally programmed by the heating.

Accordingly, the invention provides, in a very simple way, without modifying the usual manufacturing process of a MOS integrated circuit, an efficient anti-fuse cell.

According to an advantage of the invention, as confirmed by experiments made by the inventors, the anti-fuse according to the invention can be programmed by applying a relatively low voltage to the above-mentioned resistive conductive track 24. For example, in a technology wherein the gate length is about 60 nm, and by providing a conductive track of a width of 1400 nm at 60 nm from the internal side of an insulating field region having a width of about 4500 nm and a depth of about 300 nm, it will be sufficient to apply a voltage of 3.3 volts at the terminals 25, 26 of the track. This causes a current of about 120 mA to flow in the conductive track during a time that causes a power dissipation of 400 mW. Then, at the level of the transistor of the anti-fuse cell, a temperature of about 400° C. is obtained, which is sufficient to cause a diffusion of a metal such as nickel used to form the silicide contact of the MOS transistor. Thus, the cell according to the invention is programmable with a relatively low voltage compatible with CMOS technologies.

Also, in the above-indicated technology, the active area of the MOS transistor will have a total length of 300 nm and the whole surface of the anti-fuse cell, including the peripheral insulating field region, for example a STI, will be about 5 μm². So, an anti-fuse cell according to the invention is smaller than most known fuses.

According to another advantage of the present invention, the result of a desired programming can be simulated before effectively implementing the permanent programming of an array of anti-fuse cells. Before programming, each anti-fuse cell transistor can also operate as a normal transistor. Thus, before programming a set of cells, the corresponding set of transistors can be made conductive by applying a voltage on their gates. Accordingly, the result of a projected programming can be checked before implementing the programming.

According to another advantage of the invention, it will be noted that an anti-fuse cell according to the invention can be programmed in the field, after having put a chip in a package. Indeed, as the resistive track according to the invention is generally covered by a relatively thick insulating layer, commonly a CVD oxide, the heating will not result into a substantial temperature increase in the direction of the upper side of the component. This is due to the fact that, as indicated above, the silicon is more thermally conductive than an insulator and, in particular a silicon oxide. Also, the heat is drawn towards the lower side of the component, due to the fact that, usually, the lower side of a component is linked to a heat sink.

Of course, the invention is liable of many variations that will appear to those skilled in the art within the scope of the invention as defined by the appended claims. In particular, the conductive track can be made of a plurality of sections or a plurality of concentric conductive tracks could be used.

1. An anti-fuse cell including:
a MOS transistor of a MOS integrated circuit, with source (7) and drain (8) regions covered with a metal silicide layer (12, 13), and
at least one track (24) of a resistive layer at least partially surrounding said MOS transistor, and adapted to pass a heating current such that the metal of said metal silicide diffuses across drain and/or source junctions.

2. The cell of claim 1, wherein said resistive track is arranged over an insulating field region (22) surrounding said MOS transistor, close to said MOS transistor.

3. The cell of claim 2, wherein the field insulating region surrounding said MOS transistor is wider than the insulating field regions surrounding other MOS transistors of the same integrated circuit.

4. The cell of claim 1, wherein said track (24) is made of the same layer used to form the gate (5) of said MOS transistor.

5. The cell of claim 1, wherein said track (24) is provided with terminals (25, 26) for passing a current therein.

6. A method of manufacturing an anti-fuse cell in an integrated circuit including standard MOS transistors, having source and drain regions containing a layer of metal silicide and being surrounded by insulating field regions, characterized in that each anti-fuse cell is made of an additional MOS transistor, and in that said method includes the following steps:
providing insulating field regions wider for said additional transistor than for said standard MOS transistors,
forming simultaneously said additional transistor and said standard MOS transistors,
forming at least one resistive track on the insulating field region around the periphery of said additional MOS transistor, simultaneously with the conductive layer of gates of the transistors.

7. The method of claim 6, wherein the metal silicide is a nickel silicide.

8. The method of claim 6, wherein each MOS transistor has a gate length smaller than 100 nm.

9. The method of claim 6, wherein each field insulating region has a width of about 200 nm around each standard transistor, and a width of about 5000 nm around each anti-fuse cell, said insulating field region having a depth of some hundreds of nm.

10. The method of claim 6, further comprising a step of programming the anti-fuse cell by applying to the resistive track a voltage in the same range as the voltages currently applied for the operation of the integrated circuit.
